(19) United States
(12) Patent Application Publication
(10) Pub. No.: US 2004/0232565 A1
(43) Pub. Date: Nov. 25, 2004

(54) Circuit device resistant to cracking and having sealing layer resistant to sagging and method for making the same

(75) Inventors: Hiroyuki Sakamoto, Fukushima-ken (JP); Kazuya Ishikawa, Fukushima-ken (JP); Seiichi Yokoyama, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/690,013

(22) Filed: Oct. 21, 2003

(30) Foreign Application Priority Data
Oct. 31, 2002 (JP) 2002-317086

(51) Int. Cl. H01L 23/28

(52) U.S. Cl. 257/787; 257/790

(57) ABSTRACT

A circuit device includes a substrate, a semiconductor chip mounted on the substrate, and a sealing layer for sealing the semiconductor chip to cover the semiconductor chip. The sealing layer includes a silicone-based material that has a thixotropic index from 2 to 6 and an elastic coefficient of 1 to 50 MPa. A shielding member is attached to the substrate and covers the sealing layer.

### BACKGROUND OF THE INVENTION

1. Field of the Invention

The present invention relates to a circuit device implementing a semiconductor bare chip on a substrate and, more particularly, it concerns the structure of a sealing layer of the semiconductor bare chip on the circuit device.

2. Description of the Related Art

Referring to FIGS. 2 and 3, a known circuit device 50 will be described. As FIG. 2 shows, the known circuit device 50 includes a semiconductor chip 32 mounted on a substrate 30 through a glazed layer 31 and an epoxy-based sealing layer 36 for sealing the semiconductor chip 32 so as to cover it. A wire 34 is disposed between the alumina substrate 30 and the semiconductor chip 32 by wire bonding to bring the semiconductor chip 32 into conduction with an external device of the circuit device 50. Furthermore, in order to shield an external electric field and the like, a shielding member 38 is provided to cover the semiconductor chip 32, the wire 34, and the sealing layer 36. The shielding member 38 is fixed to the surface of the glazed layer 31 with a silver paste 40.

In the circuit device 50 with such an arrangement, when a thermosetting epoxy-based material is solidified by heating, the substrate 30, the glazed layer 31, and the semiconductor chip 32 are easily cracked. This may be caused by a high elastic coefficient of the epoxy-based material and the difference in thermal expansion coefficient among the epoxy-based material and the substrate 30, the glazed layer 31, and the semiconductor chip 32.

Therefore, in order to solve the above problem, the use of the sealing layer 36 made of an epoxy-based material with a low elastic coefficient has also been taken into consideration. However, as FIG. 3 shows, since the sealing layer 36 made of a low-elastic-coefficient epoxy-based material tends to sag, the wire 34 was sometimes exposed from the sealing layer 36 and the sealing layer 36 sometimes reached an end-face electrode (not shown) provided on the side of the substrate 30. The sealing layer 36 sometimes expanded to thereby enter between the shielding member 38 and the glazed layer 31, thus delaminating the shielding member 38 from the glazed layer 31.

[Patent Documents]

Japanese Unexamined Published Patent Application No. H8-236652

Japanese Utility Model Registration No. 2,506,028

Japanese Unexamined Published Patent Application No. H8-213498

Japanese Unexamined Published Patent Application No. H11-233537

### SUMMARY OF THE INVENTION

Accordingly, it is an object of the present invention to provide a circuit device in which a substrate, a glazed layer, and a semiconductor chip are resistant to cracking and a sealing layer does not sag. Another object of the invention is to provide a circuit device in which a sealing layer with a desired shape can be easily formed and held.

In order to solve the above problems, a circuit device according to the present invention includes a substrate, a semiconductor chip mounted on the substrate, and a sealing layer for sealing the semiconductor chip so as to cover it. The sealing layer includes a silicone-based material.

Preferably, the thixotropic index of the silicone-based material is from 2 to 6 and the elastic coefficient of the silicone-based material is from 1 to 50 MPa.

Preferably, the circuit device according to the invention further includes a shielding member arranged on the substrate so as to cover the sealing layer on the substrate, and the shielding member and the substrate are soldered to each other.

A method for making the circuit device according to the invention includes the step of mounting a semiconductor chip on a substrate and the step of forming a sealing layer so as to cover the semiconductor chip. The sealing layer includes a silicone-based material.

### BRIEF DESCRIPTION OF THE DRAWINGS

FIG. 1 is a side view of a circuit device according to an embodiment of the present invention;

FIG. 2 is a side view of a conventional circuit device; and

FIG. 3 is a side view of the conventional circuit device, showing a state in which a sealing layer sags.

### DESCRIPTION OF THE PREFERRED EMBODIMENT

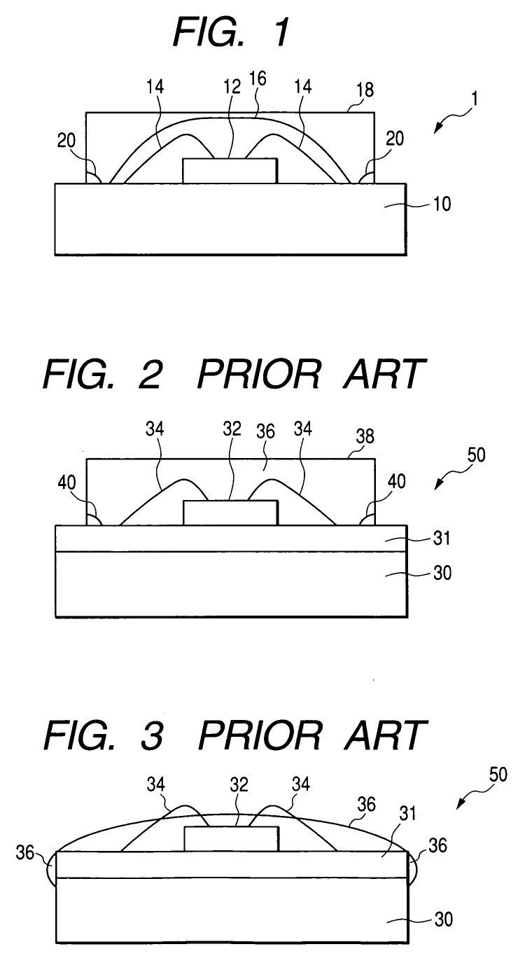

An embodiment of the present invention will be specifically described hereinafter with reference to the drawings. As FIG. 1 shows, a circuit device 1 according to the embodiment includes a semiconductor chip 12 mounted on a substrate 10 and a silicone-based sealing layer 16 for sealing the semiconductor chip 12 so as to cover it.

The alumina substrate 10 has at least one semiconductor chip 12 formed thereon in a desired pattern. A wire 14 is disposed between the semiconductor chip 12 and the substrate 10 by wire bonding for conduction of electricity between the semiconductor chip 12 and a device outside the circuit device 1 through a conductive pattern (not shown) formed on the substrate 10.

The sealing layer 16 is formed by potting on the substrate 10 having the semiconductor chip 12 and the wire 14. The sealing layer 16 is provided to protect the semiconductor chip 12 and the wire 14 by sealing and uses a silicone-based material such as a junction coating agent in this embodiment. The silicone-based material preferably has an elastic coefficient (Young's modulus) within the range from 1 to 50 MPa and a thixotropic index (thixo index) within the range from 2 to 6. The use of the silicone-based material within the range offers the following advantages. The thixotropic index here denotes an index that indicates the degree of thixotropy in which apparent viscosity is temporarily decreased owing to deformation even in an isothermal condition. The higher the value is, the higher the temporary decrease in apparent viscosity is. Therefore, those that have a high thixotropic index, like the silicone-based material of this embodiment, can be sufficiently decreased in viscosity by mixing or the like even if it has relatively high viscosity during storage. The thixotropic index was measured at a rotation number of 2 rpm and 20 rpm (temperature: 25° C.) with a BH viscometer.

The use of the silicone-based material with such an elastic coefficient and a thixotropic index as the material for the sealing layer 16 allows the silicone-based material to be decreased in viscosity to facilitate working by mixing when the silicone-based material is potted to the semiconductor chip 12 and the wire 14. Since the viscosity increases as it is left standing after the potting, the sealing layer 16 does not expand to the side of the substrate 10 and is also formed selectively on the semiconductor chip 12 in an arbitrary area on the substrate 10, or in a desired area and height by a short-time working. Accordingly, the wire 14 is not exposed to the exterior of the sealing layer 16.

Furthermore, since the sealing layer 16 is made of a silicone-based material, there is no need to heat the sealing layer 16, thus posing no problem of forming cracks owing to the difference in thermal expansion coefficient between the substrate 10 and the semiconductor chip 12. Also providing a grazed layer (glass layer) between the substrate 10 and the semiconductor chip 12 in order to improve the surface roughness for the purpose of increasing the reliability of the semiconductor chip 12 on the substrate 10 may similarly cause no crack.

Even if the silicone-based material is left standing after the potting, it is not solidified, being maintained in an elastic condition. Therefore, even if the silicone-based material increases in viscosity after the completion of potting, no crack is formed in the substrate 10 and the semiconductor chip 12, which is similar to the case in which the grazed layer is provided between the substrate 10 and the semiconductor chip 12.

In this embodiment, in order to shield an external electric field and the like, after the sealing layer 16 has been formed, a shielding member 18 is provided so as to cover the semiconductor chip 12, the wire 14, and the sealing layer 16 on the substrate 10. The shielding member 18 is fixed to the surface of the substrate 10 with solder 20.

Since the solder 20 is used to fix the shielding member 18 and the substrate 10 to each other, the shielding member 18 is firmly secured to the substrate 10. Since the sealing layer 16 is formed of a silicone-based material with a high thixotropic index, the sealing layer 16 does not sag. Therefore, the shielding member 18 and the sealing layer 16 are held separately from each other. Accordingly, the shielding member 18 is not disconnected from the substrate 10 by the sealing layer 16 entering between the shielding member 18 and the substrate 10.

The measurement of the electrical characteristics of the circuit device 1 according to the embodiment shows that εγ=2.76 and tanδ=0.001 at 1 GHz where εγ is an electric constant and tanδ is a loss factor, which has proved that the characteristics have no problem in practical use.

While the present invention has been described with reference to the foregoing embodiment, it is to be understood that the invention is not limited to the embodiment and various improvements and modifications may be made within the spirit and the scope of the invention.

As described above, the present invention provides a circuit device in which the substrate, the glazed layer, and the semiconductor chip are resistant to cracking and in which the sealing layer does not sag by using a sealing layer made of a silicone-based material with an elastic coefficient of 1 to 50 MPa and a thixotropic index of 2 to 6. Also the invention provides a circuit device in which a sealing layer with a desired shape can be easily formed and held.

1. A circuit device comprising:
a substrate;
a semiconductor chip mounted on the substrate; and
a sealing layer for sealing the semiconductor chip so as to cover the semiconductor chip, wherein
the sealing layer comprises a silicone-based material.

2. A circuit device according to claim 1, wherein a thixotropic index of the silicone-based material is from 2 to 6.

3. A circuit device according to claim 1, wherein an elastic coefficient of the silicone-based material is from 1 to 50 MPa.

4. A circuit device according to claim 1, further comprising a shielding member arranged on the substrate so as to cover the sealing layer on the substrate, wherein the shielding member and the substrate are soldered to each other.

5. A method for making a circuit device, comprising:
mounting a semiconductor chip on a substrate; and
forming a sealing layer so as to cover the semiconductor chip, wherein
the sealing layer comprises a silicone-based material.

6. A method for making a circuit device according to claim 5, wherein a thixotropic index of the silicone-based material is from 2 to 6.

7. A method for making a circuit device according to claim 5, wherein an elastic coefficient of the silicone-based material is from 1 to 50 MPa.

8. A method for making a circuit device according to claim 5, wherein the circuit device comprises a shielding member arranged on the substrate so as to cover the sealing layer on the substrate, and the method further comprises soldering the shielding member and the substrate to each other.
